(19) United States
(12) Patent Application Publication
(10) Pub. No.: US 2012/0326170 A1
(43) Pub. Date: Dec. 27, 2012

(54) WAFER LEVEL MOLDED OPTO-COUPLERS

(76) Inventors: Yong Liu, Scarborough, ME (US); Qiuxiao Qian, Suzhou (CN)

(21) Appl. No.: 13/166,697

(22) Filed: Jun. 22, 2011

(51) Int. Cl. H01L 33/48; H01L 33/62

(52) U.S. Cl. 257/82; 438/25; 257/E33.056; 257/E33.058

(57) ABSTRACT

Optocoupler packages and methods of making the same. An exemplary package comprises a substrate having a first surface, a second surface opposite the first surface, and a body of electrically insulating material disposed between the first and second surfaces; a first optoelectronic device embedded in the body of electrically insulating material of the substrate and disposed between the substrate's first and second surfaces, the first optoelectronic device having a first conductive region and a second conductive region; a second optoelectronic device embedded in the body of electrically insulating material of the substrate and disposed between the substrate's first and second surfaces and optically coupled to the first optoelectronic device, the second optoelectronic device having a first conductive region and a second conductive region; and a plurality of electrical traces disposed on one or both surfaces of the substrate and electrically coupled to the conductive regions of the optoelectronic devices.

### CROSS-REFERENCES TO RELATED APPLICATIONS

None.

### BACKGROUND OF THE INVENTION

An optocoupler contains an optical emitter device that is optically coupled to an optical receiver device through an optically transmissive material. This arrangement permits the passage of information from one electrical circuit that contains the optical emitter device to another electrical circuit that contains the optical receiver device. A high degree of electrical isolation is maintained between the two circuits. Because information is passed optically across an electrically insulating gap, the transfer is one way. For example, the optical receiver device cannot modify the operation of a circuit containing the optical emitter device. This feature is desirable because, for example, the emitter may be driven by a low voltage circuit using a microprocessor or logic gates, while the output optical receiver device may be part of a high voltage DC or AC load circuit. The optical isolation also prevents damage to the input circuit caused by the relatively hostile output circuit, and allows the two circuits to be at different ground potentials.

### BRIEF SUMMARY OF THE INVENTION

As part of making their invention, the inventors have recognized that optocouplers are being used in greater numbers in power conversion circuits, and that the relatively bulky size of multiple optocouplers in a power conversion circuit will be an impediment to allowing the size and volume of the circuit to be reduced. Also as part of making their invention, the inventors have recognized that there is a need to reduce the costs of optocouplers and to increase their electrical performance. Aspects of the present invention provide optocouplers with optoelectronic components embedded within a support substrate, and one or more ultra thin interconnect layers, which each provide for an ultra thin and ultra-small optocoupler package. The construction enables the support substrate and embedded components to be manufactured with a wafer-level molding and manufacturing processes in which multiple instances of the package are manufacture together on a common wafer using a common molding process and conventional semiconductor processes, and separated from the common wafer and one another after fabrication. This wafer-level manufacture approach can be automated to a high degree, which significantly lowers manufacturing costs. Further aspects of the present invention reduce manufacturing costs and improve electrical performance.

Accordingly, a first general exemplary embodiment according to the present invention is directed to an optocoupler package comprising: a substrate having a first surface, a second surface opposite to the first surface, and a body of electrically insulating material disposed between the first and second surfaces, a first optoelectronic device embedded in the body of electrically insulating material of the substrate and disposed between the substrate's first and second surfaces, the first optoelectronic device having a first conductive region and a second conductive region, and a second optoelectronic device embedded in the body of electrically insulating material of the substrate and disposed between the substrate's first and second surfaces and optically coupled to the first optoelectronic device, the second optoelectronic device having a first conductive region and a second conductive region. The exemplary optocoupler package further comprises: a first electrical trace disposed on a surface of the substrate and electrically coupled to the first conductive region of the first optoelectronic device, a second electrical trace disposed on a surface of the substrate and electrically coupled to the second conductive region of the first optoelectronic device, a third electrical trace disposed on a surface of the substrate and electrically coupled to the first conductive region of the second optoelectronic device, and a fourth electrical trace disposed on a surface of the substrate and electrically coupled to the second conductive region of the second optoelectronic device. The first and second optoelectronic devices may be optically coupled together by a body of radiation transmissive material disposed at or on the first surface of the substrate and over the first and second optoelectronic devices.

A second general exemplary embodiment according to the present invention is directed to a method of manufacturing an optocoupler package comprising: molding a body of electrically insulating material around a first optoelectronic device and a second optoelectronic device to form a substrate having a first surface and a second surface opposite to the first surface, with the body of electrically insulating material being disposed between the first and second surfaces, the first optoelectronic device being embedded in the body of electrically insulating material and disposed between the substrate's first and second surfaces, the first optoelectronic device having a first conductive region and a second conductive region, and the second optoelectronic device being embedded in the body of electrically insulating material and disposed between the substrate's first and second surfaces, the second optoelectronic device having a first conductive region and a second conductive region. The exemplary method further comprises forming a first electrical trace disposed on a surface of the substrate and electrically coupled to the first conductive region of the first optoelectronic device, forming a second electrical trace disposed on a surface of the substrate and electrically coupled to the second conductive region of the first optoelectronic device, forming a third electrical trace disposed on a surface of the substrate and electrically coupled to the first conductive region of the second optoelectronic device, forming a fourth electrical trace disposed on a surface of the substrate and electrically coupled to the second conductive region of the second optoelectronic device; and disposing a body of radiation transmissive material on the first surface of the substrate and over the first and second optoelectronic devices such that the second optoelectronic device is optically coupled to the first optoelectronic device. The electrical traces may be formed using various combinations of electroplating and masking steps, which can be highly automated processes in the wafer-level manufacturing environment.

The above exemplary construction has many advantages. First, embedding the optoelectronic devices into the substrate reduces the thickness of package compared to prior art optocouplers where the optoelectronic devices are mounted on the surface of a substrate. Since the devices are embedded in the substrate, the body radiation transmissive material does need to encase the devices, and therefore can have a smaller height and smaller foot print area, thereby reducing the foot print area of the package. Also, the construction enables the traces to replace the wire bonds used in conventional optocoupler packages, which also reduces the height and foot print area of the packages. The elimination of wire bonds also increases the reliability of the package, enables wafer-level manufacturing processes to be used. Wafer-level processing allows for a high degree of automation, and generally results in lower costs compared to conventional lead frame methods. The smaller foot print of the package also enables a larger number of packages to be formed on a common wafer.

The above exemplary embodiments and other embodiments of the inventions are described in the Detailed Description with reference to the Figures. In the Figures, like numerals may reference like elements and descriptions of some elements may not be repeated.

### BRIEF DESCRIPTION OF THE DRAWINGS

FIG. 1 shows is a front perspective view of a first exemplary optocoupler package according to the present invention.

FIG. 2 shows is a front perspective view of a first exemplary optocoupler package according to the present invention with some components removed and with some components shown in transparent form for visual clarity.

FIG. 3 shows is a side view of a first exemplary optocoupler package according to the present invention with some components shown in semi-transparent forms for visual clarity.

FIGS. 4-13 illustrate an exemplary method of manufacturing the exemplary optocoupler package shown in FIGS. 1-3 according to the present invention.

FIGS. 14-16 illustrate a second exemplary optocoupler package and an exemplary method of manufacturing the second exemplary optocoupler package according to the present invention.

### DETAILED DESCRIPTION OF THE INVENTION

The present invention will be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to one skilled in the art. In the drawings, the thicknesses of layers and regions may be exaggerated for clarity. The same reference numerals are used to denote the same elements throughout the specification. The elements may have different interrelationships and different positions for different embodiments.

It will also be understood that when a layer is referred to as being “on” another layer or substrate, it can be directly on the other layer or substrate, or intervening layers may also be present. It will also be understood that when an element, such as a layer, a region, or a substrate, is referred to as being “on,” “connected to,” “electrically connected to,” “coupled to,” or “electrically coupled to” another element, it may be directly on, connected or coupled to the other element, or one or more intervening elements may be present. In contrast, when an element is referred to as being “directly on,” “directly connected to” or “directly coupled to” another element or layer, there are no intervening elements or layers present. The term “and/or” used herein includes any and all combinations of one or more of the associated listed items.

The terms used herein are for illustrative purposes of the present invention only and should not be construed to limit the meaning or the scope of the present invention. As used in this specification, a singular form may, unless definitely indicating a particular case in terms of the context, include a plural form. Also, the expressions “comprise” and/or “comprising” used in this specification neither define the mentioned shapes, numbers, steps, actions, operations, members, elements, and/or groups of these, nor exclude the presence or addition of one or more other different shapes, numbers, steps, operations, members, elements, and/or groups of these, or addition of these. Spatially relative terms, such as “over,” “above,” “upper,” “under,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device (e.g., optocoupler, package) in use or operation in addition to the orientation depicted in the figures. For example, if the device in the figures is turned over, elements described as “below” or “beneath” or “under” other elements or features would then be oriented “over” or “above” the other elements or features. Thus, the exemplary term “above” may encompass both an above and below orientation.

As used herein, terms such as “first,” “second,” etc. are used to describe various members, components, regions, layers, and/or portions. However, it is obvious that the members, components, regions, layers, and/or portions should not be defined by these terms. The terms are used only for distinguishing one member, component, region, layer, or portion from another member, component, region, layer, or portion. Thus, a first member, component, region, layer, or portion which will be described may also refer to a second member, component, region, layer, or portion, without departing from the scope of the present invention.

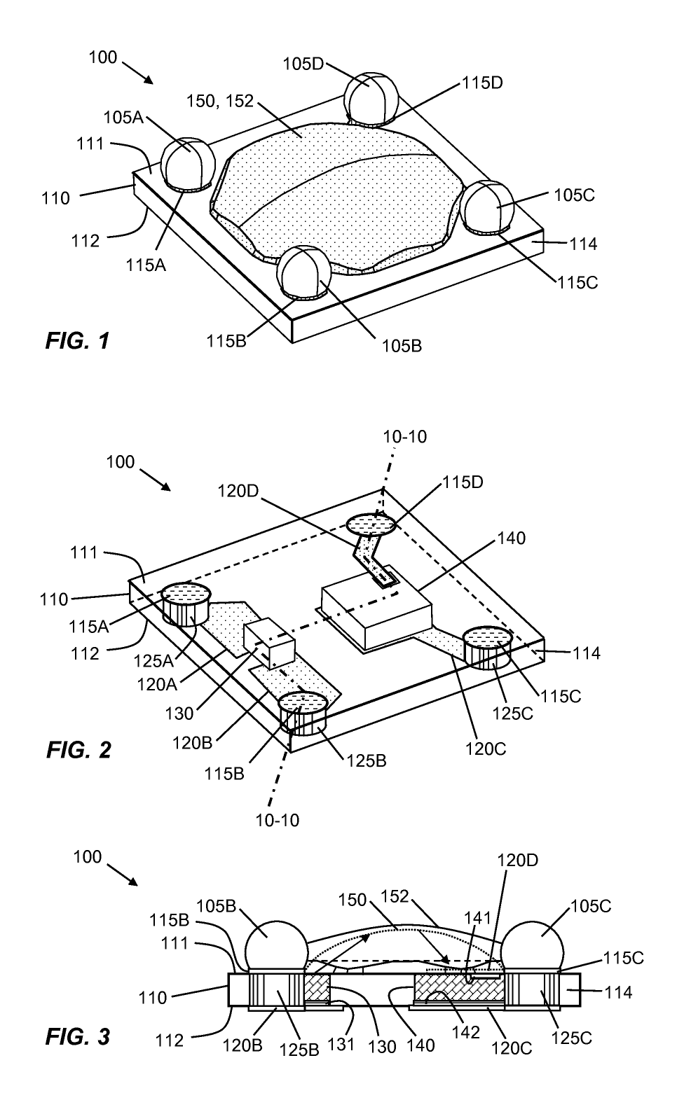

FIGS. 1-3 show a first exemplary embodiment 100 of an optoelectronic package according to the present invention. FIG. 1 is a front perspective view of package 100. Package 100 comprises a substrate 110 having a first surface 111, a second surface 112, a body 114 of electrically insulating material disposed between surfaces 111 and 112, a plurality of conductive interconnect lands 115A-115D disposed on first surface 111, an optional plurality of interconnect bumps 105A-105D disposed on lands 115A-115D, respectively, and a body 150 of a radiation transmissive material that is disposed over first surface 111 and between lands 115A-115D. A layer 152 of reflective or partially reflective material may be disposed over the top of body 150 to further enhance the coupling of radiation between the optoelectronic components of package 100.

FIG. 2 is a front perspective view of package 100 with body 150, reflective layer 152, and interconnect bumps 105A-105D removed, and with the body 114 of material of substrate 110 shown in transparent form. As seen in the figure, package 100 further comprises a first optoelectronic device 130 embedded in substrate 110 and disposed between the substrate's first and second surfaces 111-112, and a second optoelectronic device 140 embedded in substrate 110 and disposed between the substrate's first and second surfaces 111-112. Device 130 may have two electrical terminals disposed at its bottom surface, which may be near or at the substrate's second surface 112. Device 130 may comprise a radiation-emitting diode, such as a light-emitting diode, and may be in the form of a semiconductor die that has two conductive regions as its two electrical terminals, or may be in the form of a surface mount device with two electrical terminals at its bottom surface. In either form, device 130 may, in some implementations, comprise a discrete radiation-emitting device (e.g., discrete LED), where the term “discrete” means that the device is self-contained and provides a particular electrical function in lumped form, and is not integrated in combination with other components. In other implementations, device 130 may comprise driver circuitry integrated with the radiation-emitting device that provides power to the radiation-emitting device in relation to a received input signal. In such an integrated embodiment, device 130 may comprise two terminals for providing a power-supply voltage and at least one additional terminal for providing a controlling input signal.

Device 140 may have a first electrical terminal disposed at its top surface, which may be near or at the substrate's first surface 111, and a second electrical terminal disposed at its bottom surface, which may be near or at the substrate's second surface 112. Device 140 may comprise a radiation detector, such as a photodiode, and may be in the form of a semiconductor die that has two conductive regions as its two electrical terminals, or may be in the form of a surface mount device with two electrical terminals at its distal ends that cover portions of both of its top and bottom surfaces. In either form, device 140 may, in some implementations, comprise a discrete radiation-detector (e.g., discrete photodiode or phototransistor), where the term “discrete” was defined above. In other implementations, device 140 may comprise an electrical amplifier integrated with the radiation detector that amplifies the signal generated by the detector and provides the amplified signal as an output. In such an integrated embodiment, device 140 may comprise two terminals for providing a power-supply voltage and at least one additional terminal for providing the amplified output signal.

Still referring to FIG. 2, package 100 may further comprise a first electrical trace 120A disposed at the substrate's second surface 112 and electrically coupled to the first electrical terminal of device 130, a second electrical trace 120B disposed at the substrate's second surface 112 and electrically coupled to the second electrical terminal of device 130. Package 100 may further comprise a first electrically conductive pillar 125A and a second electrically conductive pillar 125B, each of which is embedded in substrate 110 and has a top surface near or at the substrate's first surface 111 and a bottom surface near or at the substrate's second surface 112. First electrical trace 120A extends to the bottom surface of first pillar 125A and is electrically coupled thereto. Second electrical trace 120B extends to the bottom surface of second pillar 125B and is electrically coupled thereto. The top surfaces of pillars 125A and 125B are electrically coupled to electrically-conductive interconnect lands 115A and 115B, respectively. Package 100 may further comprise a third electrical trace 120C disposed at the substrate's second surface 112 and electrically coupled to the second terminal of device 140, and a fourth electrical trace 120D disposed at the substrate's first surface 111 and electrically coupled to the first terminal of device 140. Package 100 may further comprise a third electrically conductive pillar 125C, which is embedded in substrate 110 and has a top surface near or at the substrate's first surface 111 and a bottom surface near or at the substrate's second surface 112. Third electrical trace 120C extends to the bottom surface of third pillar 125C and is electrically coupled thereto. The top surface of pillar 125C is electrically coupled to electrically-conductive interconnect land 115C. Fourth electrical trace 120D extends to electrically-conductive interconnect land 115D and is electrically coupled thereto.

FIG. 3 shows a side view of package 100 with bodies 114 and 150 shown in semi-transparent forms. Body 114 of electrically insulating material may be disposed such that it abuts the lateral sides of each of devices 130 and 140, and may be adhered thereto, while leaving the top surfaces of devices 130 and 140 uncovered and exposed at the substrate's first surface 111. Body 114 may also be disposed such that it leaves portions of the bottom surfaces of devices 130 and 140 uncovered and exposed at the substrate's second surface 112. Body 114 of electrically insulating material may also be disposed such that it abuts the lateral sides of each of conductive pillars 125A-125C, and may be adhered thereto, while leaving the top surfaces of the pillars uncovered and exposed at the substrate's first surface 111. Body 114 may also be disposed such that it leaves portions of the bottom surfaces of conductive pillars 125A-125C uncovered and exposed at the substrate's second surface 112. Radiation (e.g., light) radiates from the top surface of device 130 up into body 150 of radiation transmissive material, hits the interface between body 150 and reflective layer 152, and bounces down toward receiving device 140, as shown by the radiation arrows in the figure. In this manner, devices 130 and 140 are optically coupled to one another. (As used herein, “optically coupled” means that device 140 can receive the radiation transmitted by device 130, and vice versa.) To prevent optical noise in the optocoupler circuit, body 114 of the electrically insulating material is preferably optically opaque to the radiation emitted by device 130, and to the radiation band to which device 140 is sensitive. Also for a reduction in optical noise, trace 120C preferably covers the entire bottom surface of device 140 to prevent external radiation from entering device 140 from its back surface. Trace 120C may further overlap onto body 114 all around the perimeter of device 140 by at least a small amount to further prevent the entrance of radiation.

The above construction has many advantages. First, the embedding of devices 130 and 140 into substrate 110 reduces the thickness of package 100 compared to prior art optocouplers where the optoelectronic devices are mounted on the surface of a substrate. Also, since devices 130 and 140 are embedded in substrate 110, body 150 of radiation transmissive material does need to encase the devices, and therefore can have a smaller height and smaller foot print area, thereby reducing the foot print area of package 100. Also, the construction enables traces 120A-120D to replace the wire bonds used in conventional optocoupler packages, which also reduces the height and foot print area of package 100 compared to prior art optocouplers. The traces and conductive pillars also enable the use of interconnect bumps rather than leads, which further reduces the footprint area of the package. These interconnect bumps can be located in the same height volume as body 150 and layer 152, and thereby do not substantially increase the overall height of the package. The elimination of wire bonds also increases the reliability of the package, enables wafer-level manufacturing processes to be used (as illustrated below in greater detail). Wafer-level processing allows for a high degree of automation, and generally results in a less expensive cost compared to conventional lead frame methods. As a further advantage, the substrate construction eliminates the need to use temporary paper and ribbon supports to form bodies 150 of radiation transmissive material (e.g., optical gel) on unmolded lead frames (as is conventionally done). This eliminates the prior art processes of adhering a paper back support and ribbon tape to an unmolded lead frame prior to dispensing and curing the optical gel and thereafter removing the paper and ribbon, thereby saving processing time and cost.

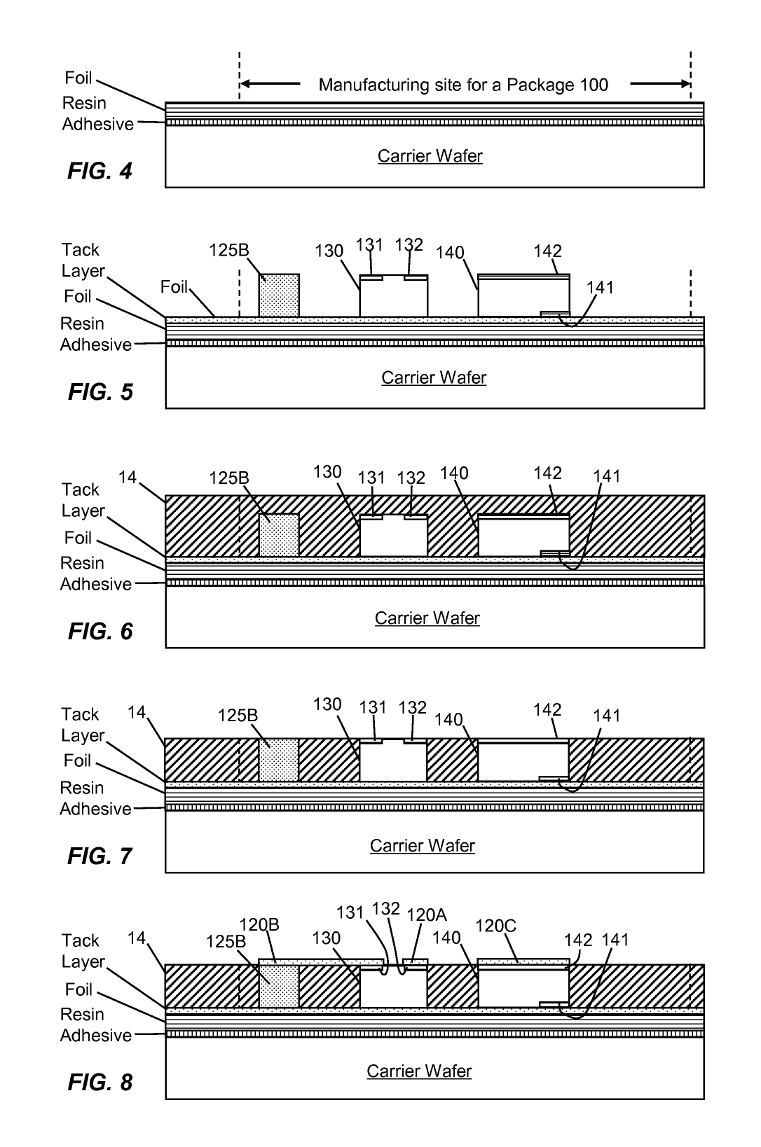

FIGS. 4-13 illustrate an exemplary method of manufacturing package 100. Referring to FIG. 4, a working substrate is made by laminating a resin-coated foil (e.g., a resin-coated copper foil, or RCC foil) to a carrier substrate, which may comprise a carrier wafer. The working substrate will be used to make a plurality of packages 100, the outline of one such package being shown in FIG. 4 and subsequent FIGS. 5-12 by a pair of dashed lines. FIGS. 4-13 show the cross-section of package 100 as taken through the line 10-10 shown in FIG. 2. Referring to FIG. 5, a thin adhesive tack layer is formed over the foil, such as by spraying, and the components 125A-125C, 130, and 140 are disposed on foil in their corresponding positions, with the tack layer keeping the components in place. Components 125A and 125C do not fall within the cross-section plane defined by line 10-10, and thus do not appear in the FIGS. 6-13, but are nonetheless present in the manufacturing process. The components are placed with their top active surfaces facing the foil. Conventional pick-and-place equipment may be used to do this. Device 130 has two conductive regions 131 and 132 disposed at its bottom surface, which is oriented to face away from the working substrate. Device 140 has a first terminal 141 disposed at its top surface, which is oriented to face the working substrate, and a second terminal 141 disposed on its bottom surface, which is oriented to face away from the working substrate. Next, referring to FIG. 6, a molding material 14 is formed over the components 125A-125C, 130, and 140 and the working substrate, such as by transfer molding. Molding material 14 encases the components and adhesively bonds itself to the components. With the transfer molding process, excess molding material is formed over the bottom surfaces of components 125A-125C, 130, and 140. This excess material is removed, as shown in FIG. 7. It may be removed by a sanding process, grinding process, a lapping process, a chemical-mechanical polishing (CMP) process, or a combination of two or more of these processes. The formation of the excess molding material can be avoided by using a film-assisted molding process, and the sanding, grinding, lapping, and/or CMP processes may be omitted. In film-assisted molding, a disposable thin film is held against the molding surface of the top mold plate by a vacuum, the molding surface of the top mold plate is then pressed against the bottom surfaces of components 125A-125C, 130, and 140, and molding material 14 is thereafter injected into the space between the top mold plate and working substrate, and around the sides of the components, keeping the top and bottom surfaces of the components free of molding material.

Referring to FIG. 8, a patterned conductive layer is formed over the exposed surfaces of the molding material 14 and components 125A-125C, 130, and 140 to provide electrical traces 120A-120C. Various combinations of processes may be used to form the traces. In one implementation, a thin layer of conductive material, such as a metal like copper, is electrolessly plated over the entirety of the exposed surfaces of molding material 14 and components 125A-125C, 130, and 140. The plated material makes an electrical coupling to each of conductive regions 131, 132, and 142, and to each of the exposed end surfaces of conductive pillars 125A-125C. The plated material also preferably makes a metallurgical bond to each of conductive regions 131, 132, and 142, and to each of the exposed end surfaces of conductive pillars 125A-125C. (As used herein, metallurgical bond means that metal atoms of the plated material are disposed adjacent to atoms of the conductive region or pillar end surface and adhered thereto by at least weak atomic forces.)

Then a patterned mask layer is formed over the layer of conductive material to cover the areas where the traces are to be formed. Thereafter, the exposed portions of the conductive layer are etched away to leave traces 120A-120C. The patterned mask layer, which may comprise a photoresist, may be left in place or removed with a suitable solvent. Electrolytic plating may be used in combination with an electroless plating process, and suitable surface activation processes known to the art may be used to prepare the surfaces for electroless plating. In another implementation, a patterned mask layer is disposed over the exposed surfaces of molding material 14 and components 125A-125C, 130, and 140 prior to forming traces 120A-120C. This mask covers the areas where the traces are not to be formed, and leaves exposed the areas where the traces are to be formed. A thin layer of conductive material, such as a metal like copper, is electrolessly plated onto the surfaces that are left exposed by the patterned mask layer to form the traces. The plated material makes an electrical coupling to conductive regions 131, 132, and 142, and to the exposed end surfaces of conductive pillars 125A-125C. The patterned mask layer, which may comprise a photoresist, may be left in place or removed with a suitable solvent. In yet another implementation, a seed plating layer of conductive material, such as a metal like copper, is electrolessly plated over the entirety of the exposed surfaces of molding material 14 and components 125A-125C, 130, and 140. The seed layer makes an electrical coupling to conductive regions 131, 132, and 142, and to the exposed end surfaces of conductive pillars 125A-125C. Next, a patterned mask layer is disposed over the seed layer, covering the areas where the traces are not to be formed, and leaving exposed the areas where the traces are to be formed. A layer of conductive material, such as a metal like copper, is electrolytically plated onto the portions of the seed layer that are left exposed by the patterned mask layer to form the traces. The patterned layer is then removed with a solvent, and the exposed portions of the seed layer are etched away with an etchant. Each of the above process approaches results in traces 120A-120C being electrically coupled and metallurgically bonded to conductive regions 131, 132, and 142 and the exposed end surfaces of conductive pillars 125A-125C.

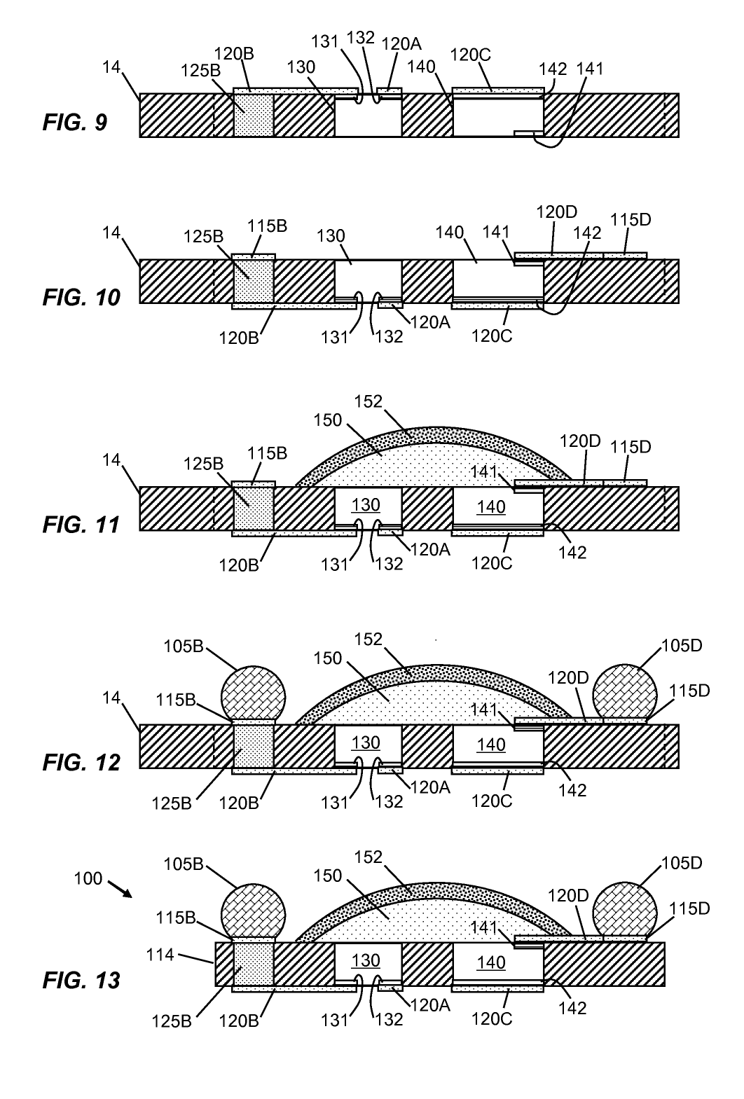

Referring to FIG. 9, the package layer formed thus far is de-bonded from the working substrate. This may be accomplished by dissolving the tack layer with a suitable solvent, or by etching the foil with a suitable etchant. In either case, a protective wax layer may be disposed over the top surface of the package layer before dissolving the tack layer or etching the foil layer. Referring next to FIG. 10, the package layer is turned over, and trace 120D and lands 115A-115D are formed on the top surface of the package layer. Various combinations of processes may be used to form the trace and lands, including the exemplary combination of processes described above for forming traces 120A-120C. Briefly, one approach comprises electrolessly plating a conductive layer over the top surface of the package substrate, disposing a patterned etch mask, etching away unwanted portions of the conductive layer to leave the desired trace and lands, followed by optionally removing the patterned etch mask. Another approach may comprise forming a patterned etch mask over the top surface of the package layer, electrolessly plating conductive material into the voids of the etch mask to provide the desired trace and lands, followed by optionally removing the patterned etch mask. Another approach may comprise electrolessly plating a seed layer over the top surface of the package layer, forming a patterned etch mask over the seed layer, electrolytically plating conductive material into the voids of the etch mask to provide the desired trace and lands, followed by removing the patterned etch mask. Each of the above process approaches results in trace 120D being electrically coupled and metallurgically bonded to conductive region 141.

Referring to FIG. 11, a body 150 of a radiation transmissive material is disposed over devices 130 and 140 and solidified, such as by curing at an elevated temperature. Next, a layer 152 of reflective or partially reflective material may be disposed over the top of body 150 to further enhance the coupling of radiation. Referring to FIG. 12, a plurality of interconnect bumps 105A-105D are disposed on interconnect lands 115A-115D. Interconnect bumps 105A-105D may comprise solder bumps. Referring to FIG. 13, the packages 100 are separated from the wafer-sized package layer into individual packages 100 (e.g., singulated), which may be done by sawing, laser cutting, etc.

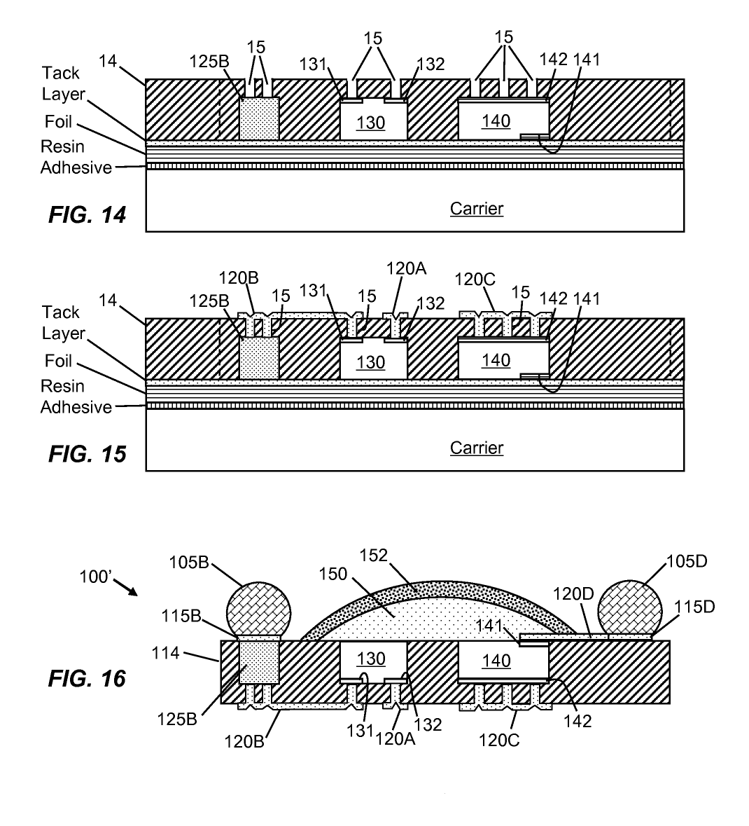

As indicated above with reference to FIG. 6, if a transfer molding process was used to form molding material 14 in the above-described exemplary method, then a process of removing the excess molding material was employed so as to uncover the bottom surfaces of devices 130 and 140 and conductive pillars 125A-125C. The following second manufacturing process may be used so as to omit this removal process. The second exemplary embodiment comprises the same processes that lead up to the formation of molding material 14 in FIG. 6. Then, referring to FIG. 14, a plurality of apertures 15 are formed through the excess portion of material 14 laser drilling (e.g., CO₂ laser drilling) in locations above the components 125A-125C, 130, and 140, until the apertures reach the bottom surfaces of the components. Preferably, two or more apertures 15 are formed over each conductive region of each component.

Referring to FIG. 15, a patterned conductive layer is formed over the exposed surfaces of the molding material 14, apertures 15, and components 125A-125C, 130, and 140 to provide electrical traces 120A-120C. Various combinations of processes may be used to form traces 120A-120C, including the exemplary combination of processes described above with reference to FIG. 8. Briefly, an approach may comprise electrolessly plating a conductive layer over the top surface of the package substrate and side and bottom surfaces of apertures 15, disposing a patterned etch mask, etching away unwanted portions of the conductive layer to leave the desired traces 120A-120C, followed by optionally removing the patterned etch mask. Another approach may comprise forming a patterned etch mask over the top surface of the package layer, electrolessly plating conductive material into the voids of the etch mask to provide the desired traces 120A-120C and filling of apertures 15, followed by optionally removing the patterned etch mask. Another approach may comprise electrolessly plating a seed layer over the top surface of the package layer and side and bottom surfaces of apertures 15, forming a patterned etch mask over the seed layer, electrolytically plating conductive material into the voids of the etch mask to provide the desired traces 120A-120C, followed by removing the patterned etch mask. Each of the above process approaches results in traces 120A-120C being electrically coupled and metallurgically bonded to conductive regions 131, 132, and 142 and the exposed end surfaces of conductive pillars 125A-125C.

Next, the package layer formed thus far is de-bonded from the working substrate, as was similarly done in the first exemplary described method with reference to FIG. 9. This may be accomplished by dissolving the tack layer with a suitable solvent, or by etching the foil with a suitable etchant, as in the first exemplary method. Next, the package layer is turned over, and trace 120D and lands 115A-115D are formed on the top surface of the package layer, as was done in the first exemplary described method with reference to FIG. 10. Any of the above combination of processes may be used. The following processes of the first exemplary method are then conducted: a body 150 of a radiation transmissive material is disposed over devices 130 and 140 and solidified, such as by curing at an elevated temperature; a layer 152 of reflective or partially reflective material may be disposed over the top of body 150 to further enhance the coupling of radiation; a plurality of interconnect bumps 105A-105D are disposed on interconnect lands 115A-115D; and the packages are separated from the wafer-sized package layer into individual packages 100′ (e.g., singulated), as shown in FIG. 16.

Instead of plating, or in addition thereto, the traces 120A-120D may be formed by a sputtering process conducted under a vacuum. In general, sputtering can be advantageous for depositing seed layers for electroplating. Like plating, the sputtering process provides for metallurgical bonding of the traces to the conductive regions of the devices and the end surfaces of the conductive pillars. Plating and sputtering eliminate the need for solder joints, and have the advantages of reducing processing temperatures and increasing yield and reliability. Thus, the connections of the traces 120A-120D to the conductive regions of the optoelectronic devices and to the conductive pillars are solderless.

Each of the above processes described with reference to FIGS. 4-16, taken individually, is known in the art and can be practiced by one of ordinary skill in the art without undue experimentation. In view of the disclosure herein, one of ordinary skill in the art will be able to practice the above combinations and sequences of processes that define the inventive methods according to the present invention without undue experimentation. In addition, while wafer-level manufacturing with wafer-level molding has been described above, it may be appreciated that panel-level manufacturing with panel-level molding may be used as well.

It may be further appreciated that devices 130 and 140 may be provided in die form in which both of their conductive regions (e.g., terminals) are provided at their top active surfaces. In this case, all of the traces 120A-120D can be formed on the first surface 111 of substrate 110, and conductive pillars 125A-125C may be omitted in such implementations. If one or more of the conductive pillars 125A-125C are used, each may have a width-to-height ratio that is greater than 0.5, and may be in the range of 0.5 to 4, and more typically in the range of 1 to 4 or 2 to 4. In this ratio, the height is the dimension that spans between the first and second surfaces 111 and 112 of substrate 110, and the width is perpendicular to the height dimension, with the width being measured at its minimum value. With these ranges of width-to-height ratios, the pillars may be placed on the working substrate more easily and reliably during manufacturing.

It should be understood that where the performance of an action of any of the methods disclosed and claimed herein is not predicated on the completion of another action, the actions may be performed in any time sequence (e.g., time order) with respect to one another, including simultaneous performance and interleaved performance of various actions. (Interleaved performance may, for example, occur when parts of two or more actions are performed in a mixed fashion.) Accordingly, it may be appreciated that, while the method claims of the present application recite sets of actions, the method claims are not limited to the order of the actions listed in the claim language, but instead cover all possible orderings, including simultaneous and interleaving performance of actions and other possible orderings not explicitly described above, unless otherwise specified by the claim language (such as by explicitly stating that one action precedes or follows another action).

The packages described above can be used in electrical assemblies including circuit boards with the packages mounted thereon. They may also be used in systems such as power converters, computers, communication equipment, etc. It may be appreciated that additional optoelectronic devices may be assembled on either or both sides of the substrate to provide additional optocouplers.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. An optocoupler package comprising:
a substrate having a first surface, a second surface opposite to the first surface, and a body of electrically insulating material disposed between the first and second surfaces;
a first optoelectronic device embedded in the body of electrically insulating material of the substrate and disposed between the substrate's first and second surfaces, the first optoelectronic device having a first conductive region and a second conductive region;
a second optoelectronic device embedded in the body of electrically insulating material of the substrate and disposed between the substrate's first and second surfaces and optically coupled to the first optoelectronic device, the second optoelectronic device having a first conductive region and a second conductive region;
a first electrical trace disposed on a surface of the substrate and electrically coupled to the first conductive region of the first optoelectronic device;
a second electrical trace disposed on a surface of the substrate and electrically coupled to the second conductive region of the first optoelectronic device;
a third electrical trace disposed on a surface of the substrate and electrically coupled to the first conductive region of the second optoelectronic device; and
a fourth electrical trace disposed on a surface of the substrate and electrically coupled to the second conductive region of the second optoelectronic device.

2. The optocoupler package of claim 1, wherein at least one electrical trace is metallurgically bonded to a conductive region of the first optoelectronic device, and at least one electrical trace is metallurgically bonded to a conductive region of the second optoelectronic device.

3. The optocoupler package of claim 1, wherein the body of electrically insulating material is adhesively bonded to each of the first and second optoelectronic devices.

4. The optocoupler package of claim 1, further comprising a body of radiation transmissive material disposed on the first surface of the substrate and over the first and second optoelectronic devices.

5. The optocoupler package of claim 4, wherein the first optoelectronic device has a first surface disposed at the first surface of the substrate, and a second surface opposite to its first surface, and wherein the first and second conductive regions of the first optoelectronic device are disposed at the second surface of the first optoelectronic device.

6. The optocoupler package of claim 1, further comprising an electrically-conductive pillar embedded in the body of electrically insulating material of the substrate and disposed between the substrate's first and second surfaces, the electrically-conductive pillar having a first end disposed closer to the substrate's first surface than the substrate's second surface, and a second end opposite to the first end and disposed closer to the substrate's second surface than the substrate's first surface; and
wherein one of the conductive traces has a portion that is disposed over an end of the electrically-conductive pillar and metallurgically bonded thereto.

7. The optocoupler package of claim 1, wherein the first optoelectronic device has a first surface disposed at the first surface of the substrate, and a second surface opposite to its first surface;
wherein the second optoelectronic device has a first surface disposed at the first surface of the substrate, and a second surface opposite to its first surface; and
wherein the substrate's body of electrically insulating material covers the second surfaces of the first and second optoelectronic devices.

8. The optocoupler package of claim 7, further comprising an aperture disposed in the substrate's body of electrically insulating material between the substrate's second surface and the second surface of one of the optoelectronic devices.

9. The optocoupler package of claim 1, further comprising:
a body of radiation transmissive material disposed on the first surface of the substrate and over the first and second optoelectronic devices;
a plurality of interconnect lands disposed on the first surface of the substrate and spatially separated from the body of radiation transmissive material, each interconnect land being electrically coupled to at least one of the electrical traces; and
a plurality of interconnect bumps, each interconnect bump being disposed on a respective interconnect land.

10. The optocoupler package of claim 1, wherein the substrate's body of electrically insulating material comprises material that is opaque to radiation emitted by one of the optoelectronic devices.

11. The optocoupler package of claim 1, wherein the second optoelectronic device has a first surface disposed at the first surface of the substrate, and a second surface disposed at the second surface of the substrate; and
wherein the fourth electrical trace is disposed over the entire second surface of the second optoelectronic device.

12. A method of making an optocoupler package, the method comprising:
molding a body of electrically insulating material around a first optoelectronic device and a second optoelectronic device to form a substrate having a first surface and a second surface opposite to the first surface, with the body of electrically insulating material being disposed between the first and second surfaces, the first optoelectronic device being embedded in the body of electrically insulating material and disposed between the substrate's first and second surfaces, the first optoelectronic device having a first conductive region and a second conductive region, and the second optoelectronic device being embedded in the body of electrically insulating material and disposed between the substrate's first and second surfaces, the second optoelectronic device having a first conductive region and a second conductive region;
forming a first electrical trace disposed on a surface of the substrate and electrically coupled to the first conductive region of the first optoelectronic device;
forming a second electrical trace disposed on a surface of the substrate and electrically coupled to the second conductive region of the first optoelectronic device;
forming a third electrical trace disposed on a surface of the substrate and electrically coupled to the first conductive region of the second optoelectronic device;
forming a fourth electrical trace disposed on a surface of the substrate and electrically coupled to the second conductive region of the second optoelectronic device; and
disposing a body of radiation transmissive material on the first surface of the substrate and over the first and second optoelectronic devices such that the second optoelectronic device being optically coupled to the first optoelectronic device.

13. The method of claim 12, wherein molding the body of electrically insulating material comprises a film-assisted molding process.

14. The method of claim 12, wherein molding the body of electrically insulating material comprises a transfer molding process.

15. The method of claim 14, wherein molding the body of electrically insulating material comprises molding material over the second surfaces of the first and second optoelectronic devices, and thereafter removing the molding material at the second surface of the substrate to expose the second surfaces of the first and second optoelectronic devices.

16. The method of claim 12, wherein forming the first electrical trace comprises electroplating material onto at least a portion of a surface of the substrate and at least a portion of the first conductive region of the first optoelectronic device such that the electroplated material is metallurgically bonded to said first conductive region.

17. The method of claim 12, wherein molding the body of electrically insulating material comprises molding the body around an electrically-conductive pillar such that the pillar is embedded in the body of electrically insulating material and disposed between the substrate's first and second surfaces, the electrically-conductive pillar having a first end disposed closer to the substrate's first surface than the substrate's second surface, and a second end opposite to the first end and disposed closer to the substrate's second surface than the substrate's first surface; and
wherein forming one of the conductive traces further comprises forming the trace such that it has a portion that is disposed over an end of the electrically-conductive pillar and metallurgically bonded thereto.

18. The method of claim 12 wherein forming the first conductive trace comprises:
forming an aperture in the body of electrically insulating material from the second surface of the substrate to a conductive region of the first optoelectronic device; and
disposing conductive material in the aperture.

19. The method of claim 12, further comprising:
forming a plurality of interconnect lands at the first surface of the substrate and spatially separated from the body of radiation transmissive material, each interconnect land being electrically coupled to at least one of the electrical traces; and
forming a plurality of interconnect bumps, each interconnect bump being disposed on a respective interconnect land.

20. The method of claim 12, wherein molding the body of electrically insulating material around the first and second optoelectronic devices to form the substrate comprises:
disposing the first and second optoelectronic devices on a common wafer along with other instances of optoelectronic devices for corresponding other instances of the optocoupler package; and
molding the body of electrically insulating material over the optoelectronic components and the common wafer such that molded body spans across the instances of the optocoupler package.
